(19) United States
(12) Patent Application Publication
(10) Pub. No.: US 2026/0239798 A1
(43) Pub. Date: Aug. 13, 2026

(54) DISPLAY DEVICE AND METHOD FOR MANUFACTURING SAME

(71) Applicant: SAMSUNG ELECTRONICS CO., LTD., Suwon-si (KR)

(72) Inventors: Sungjun KOH, Suwon-si (KR); Kihyung KANG, Suwon-si (KR)

(73) Assignee: SAMSUNG ELECTRONICS CO., LTD., Suwon-si (KR)

(21) Appl. No.: 19/639,967

(22) Filed: Apr. 6, 2026

Related U.S. Application Data
(63) Continuation of application No. PCT/KR2024/012998, filed on Aug. 30, 2024.

(30) Foreign Application Priority Data
Oct. 6, 2023 (KR) 10-2023-0133202

(51) Int. Cl. H10H 29/851; H10H 29/01; H10H 29/85; H10H 29/855

(52) U.S. Cl. CPC H10H 29/8512; H10H 29/0361; H10H 29/8517; H10H 29/855

(57) ABSTRACT

A display device including a display panel for displaying an image; and a display driver IC for controlling the display panel, is provided. The display panel may include: a lower substrate including at least one light-emitting element; and an upper substrate including a color filter layer and a color conversion layer. The color conversion layer of the upper substrate may include at least one color conversion part having a rod shape. The at least one color conversion part may convert a wavelength of light by including at least one color conversion particle that is regularly arranged, and may be continuously formed at predetermined intervals on the upper substrate.

### CROSS REFERENCE TO RELATED APPLICATIONS

This application is a Continuation Application of International Application PCT/KR2024/012998, filed on August 30, 2024, which claims benefit of Korean Patent Application No. 10-2023-0133202, filed on October 6, 2023, at the Korean Ministry of Intellectual Property, the disclosures of which are incorporated herein in their entireties by reference.

### BACKGROUND

### 1. Field

Various embodiments of the disclosure relate to a display device including a color filter and a color conversion portion, and a method for manufacturing the same.

### DESCRIPTION OF THE RELATED ART

Display devices are devices that process image signals and image data input from the outside or stored internally through various processes and display them as images on a display panel or screen and may be implemented as various ones, such as TVs, monitors, or portable media players.

Recently, a display device including a lower substrate including a light emitting element and an upper substrate including a color filter and a color conversion portion has been proposed. For example, the color conversion portion may convert the wavelength of light provided from the lower substrate. Accordingly, the display device including the color conversion portion may emit light having a different color from the incident light. For example, the color conversion portion may include color conversion particles such as quantum materials. Such a color conversion particle may contribute to enhancement of display quality by being utilized as a light emitting material of the display device.

### SUMMARY

Various embodiments of the disclosure may provide a display device in which the color conversion particle inside the color conversion layer is regularly arranged by forming the color conversion layer using electrohydrodynamic printing, and a method for manufacturing the same.

A display device according to embodiments of the disclosure may include a display panel displaying an image, and a display driver IC controlling the display panel. The display panel may include a lower substrate including at least one light emitting element, and an upper substrate including a color filter layer and a color conversion layer. The color conversion layer of the upper substrate may include at least one color conversion portion having a rod shape. The at least one color conversion portion may convert a wavelength of light by including at least one color conversion particle regularly arranged, and may be continuously formed on the upper substrate at a regular interval.

In one or more embodiments, the at least one color conversion portion may be continuously disposed at a first interval with an adjacent homogeneous color conversion portion and continuously disposed at a second interval with an adjacent heterogeneous color conversion portion, by a color conversion ink including the at least one color conversion particle being ejected onto the upper substrate using electrohydrodynamic (EHD) printing.

In one or more embodiments, the at least one color conversion particle may include a quantum rod having a cylindrical shape.

In one or more embodiments, the color conversion layer may include the at least one color conversion portion formed in the rod shape between partition walls, based on the upper substrate moving in a predetermined direction along a virtual center line when the color conversion ink is ejected.

In one or more embodiments, the quantum rod may be aligned parallel to an ejection direction of the color conversion ink inside the color conversion layer, by being subjected to a first force based on a shear stress inside a Taylor cone formed as the color conversion ink is ejected from a nozzle.

In one or more embodiments, the quantum rod may be aligned parallel to an ejection direction of the color conversion ink inside the color conversion layer, by the dipole moment inside the quantum rod being subjected to a second force based on an electric field.

In one or more embodiments, the quantum rod may have the length of the major axis of the cylindrical shape ranging from 20 nm to 200 nm and the length of the diameter of the cylindrical shape ranging from 3 nm to 7 nm.

In one or more embodiments, the display panel may further include a low-reflection layer formed on the upper substrate and including a linear polarizer and a quarter wave plate.

In one or more embodiments, the linear polarizer may pass light polarized in a first direction and block light polarized in a second direction perpendicular to the first direction. The quantum rod may be aligned in a direction parallel to the first direction inside the color conversion layer.

In one or more embodiments, the upper substrate may be manufactured through a process independent from the lower substrate. The upper substrate and the lower substrate may be bonded using an optical bonding material configured to transmitting light.

A method for manufacturing a display device according to embodiments of the disclosure may include an operation of forming a lower substrate including at least one light emitting element, and an operation of forming an upper substrate including a color filter layer and a color conversion layer. The color conversion layer of the upper substrate may include at least one color conversion portion having a rod shape. The at least one color conversion portion may convert a wavelength of light by including at least one color conversion particle regularly arranged, and may be continuously formed on the upper substrate at a regular interval.

In one or more embodiments, the at least one color conversion portion may be continuously disposed at a first interval with an adjacent homogeneous color conversion portion and continuously disposed at a second interval with an adjacent heterogeneous color conversion portion, by a color conversion ink including the at least one color conversion particle being ejected onto the upper substrate using electrohydrodynamic (EHD) printing.

In one or more embodiments, the at least one color conversion particle may include a quantum rod having a cylindrical shape.

In one or more embodiments, the color conversion layer may include the at least one color conversion portion formed in the rod shape between partition walls, based on the upper substrate moving in a predetermined direction along a virtual center line when the color conversion ink is ejected.

In one or more embodiments, the operation of forming the upper substrate may align the quantum rod parallel to an ejection direction of the color conversion ink inside the color conversion layer, using a first force based on a shear stress inside a Taylor cone formed as the color conversion ink is ejected from a nozzle.

In one or more embodiments, the operation of forming the upper substrate may align the quantum rod parallel to an ejection direction of the color conversion ink inside the color conversion layer, using a second force based on an electric field acting on the dipole moment inside the quantum rod.

In one or more embodiments, the quantum rod may have the length of the major axis of the cylindrical shape ranging from 20 nm to 200 nm and the length of the diameter of the cylindrical shape ranging from 3 nm to 7 nm.

In one or more embodiments, the method for manufacturing a display device may further include an operation of forming a low-reflection layer formed on the upper substrate. The low-reflection layer may include a linear polarizer and a quarterwave plate.

In one or more embodiments, the linear polarizer may pass light polarized in a first direction and block light polarized in a second direction perpendicular to the first direction. The operation of forming the upper substrate may align the quantum rod in a direction parallel to the first direction inside the color conversion layer.

In one or more embodiments, the operation of forming the lower substrate and the operation of forming the upper substrate may be performed independently from each other. The method for manufacturing a display device may further include an operation of bonding the upper substrate and the lower substrate using an optical bonding material for transmitting light.

According to various embodiments of the disclosure, in the display device and the method for manufacturing the same of the disclosure, the color conversion particle may be regularly arranged inside the color conversion layer by forming the color conversion layer using electrohydrodynamic printing.

Further, the display device and the method for manufacturing the same of the disclosure may maximize an out-coupling region and minimize light reflected after emission, by including the quantum rod having a cylindrical shape as the color conversion particle.

Accordingly, the display device and the method for manufacturing the same of the disclosure may increase out-coupling efficiency of the color conversion layer and enhance display quality.

Effects achievable in example embodiments of the disclosure are not limited to the above-mentioned effects, but other effects not mentioned may be apparently derived and understood by one of ordinary skill in the art to which example embodiments of the disclosure pertain, from the following description. In other words, unintended effects in practicing embodiments of the disclosure may also be derived by one of ordinary skill in the art from example embodiments of the disclosure.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating an electronic device in a network environment according to one or more embodiments of the disclosure;

FIG. 2 illustrates a block configuration of a display module according to one or more embodiments;

FIG. 3 illustrates a stacked structure of a display panel according to one or more embodiments;

FIG. 4 illustrates a method of forming a color conversion layer and a transparent layer according to one or more embodiments;

FIG. 5 illustrates a structure of a color conversion particle according to one or more embodiments;

FIG. 6 illustrates a force acting in a process of forming a color conversion layer and a transparent layer according to one or more embodiments;

FIG. 7 illustrates a color conversion layer and a transparent layer formed on an upper substrate according to one or more embodiments;

FIG. 8 illustrates a stacked structure of a display panel according to another embodiment;

FIG. 9 illustrates a change of light emitted from a display panel according to one or more embodiments;

FIG. 10 illustrates an out-coupling region for each color conversion particle according to one or more embodiments;

FIG. 11 illustrates out-coupling efficiency according to a critical angle for each color conversion particle according to one or more embodiments;

FIG. 12 illustrates a stacked structure of a display panel according to one or more embodiments;

FIGS. 13A and 13B illustrate a method of forming a color conversion layer and a transparent layer according to one or more embodiments;

FIG. 14 illustrates a method for manufacturing a display device according to one or more embodiments; and

FIG. 15 illustrates an order of an operation of manufacturing a color conversion layer of an upper substrate according to one or more embodiments.

### DETAILED DESCRIPTION

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

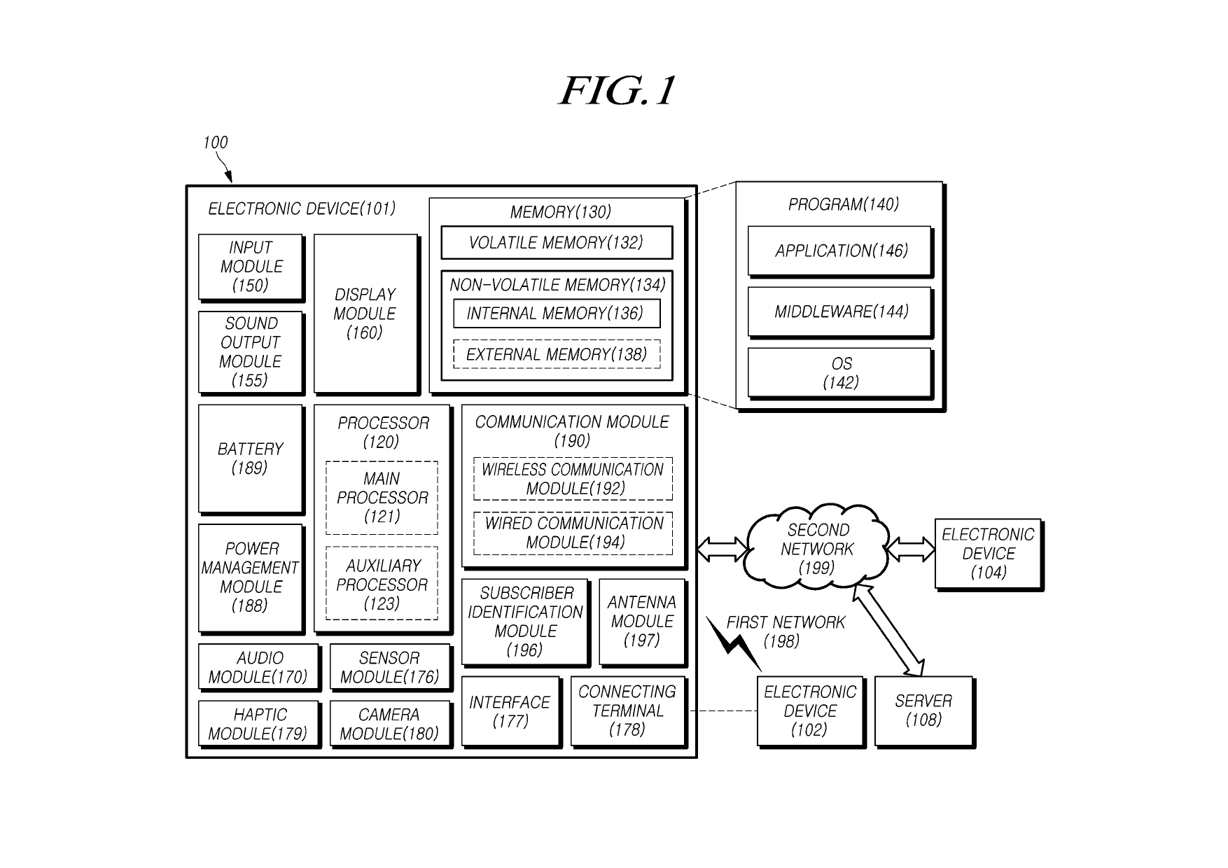

FIG. 1 is a block diagram illustrating an electronic device in a network environment according to one or more embodiments of the disclosure.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to one or more embodiments, the electronic device 101 may communicate with the electronic device 104 via the server 108. According to one or more embodiments, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In one or more embodiments, at least one (e.g., the connecting terminal 178) of the components may be omitted from the electronic device 101, or one or more other components may be added in the electronic device 101. According to one or more embodiments, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one or more embodiments, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to one or more embodiments, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to one or more embodiments, the auxiliary processor 123 (e.g., an image signal processor or a communication processor) may be implemented as part of another component (e.g., the camera module 180 or the communication module 190) functionally related to the auxiliary processor 123. According to one or more embodiments, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to one or more embodiments, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to one or more embodiments, the display module 160 may include a touch sensor configured to detect a touch, or a pressure sensor configured to measure the intensity of a force generated by the touch.

The audio module 170 may convert a sound into an electrical signal and vice versa. According to one or more embodiments, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to one or more embodiments, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to one or more embodiments, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to one or more embodiments, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to one or more embodiments, the haptic module 179 may include, for example, a motor, a piezoelectric element, or an electric stimulator.

The camera module 180 may capture a still image or moving images. According to one or more embodiments, the camera module 180 may include one or more lenses, image sensors, image signal processors, or flashes.

The power management module 188 may manage power supplied to the electronic device 101. According to one or more embodiments, the power management module 188 may be implemented as at least part of, for example, a power management integrated circuit (PMIC).

The battery 189 may supply power to at least one component of the electronic device 101. According to one or more embodiments, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to one or more embodiments, the communication module 190 may include a communication module 192 (e.g., a cellular communication module, a short-range communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The communication module 192 may identify or authenticate the electronic device 101 in a communication network, such as the first network 198 or the second network 199, using subscriber information (e.g., international mobile subscriber identity (IMSI)) stored in the subscriber identification module 196.

The communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The communication module 192 may support a high-frequency band (e.g., the mmWave band) to achieve, e.g., a high data transmission rate. The communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The communication module 192 may support various requirements specified in the electronic device 101, an external electronic device (e.g., the electronic device 104), or a network system (e.g., the second network 199). According to one or more embodiments, the communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device). According to one or more embodiments, the antenna module 197 may include one antenna including a radiator formed of a conductor or conductive pattern formed on a substrate (e.g., a printed circuit board (PCB)). According to one or more embodiments, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to one or more embodiments, other parts (e.g., radio frequency integrated circuit (RFIC)) than the radiator may be further formed as part of the antenna module 197.

According to one or more embodiments, the antenna module 197 may form a mmWave antenna module. According to one or more embodiments, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to one or more embodiments, instructions or data may be transmitted or received between the electronic device 101 and the external electronic device 104 via the server 108 coupled with the second network 199. The external electronic devices 102 or 104 each may be a device of the same or a different type from the electronic device 101. According to one or more embodiments, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an Internet-of-things (IoT) device. The server 108 may be an intelligent server using machine learning and/or a neural network. According to one or more embodiments, the external electronic device 104 or the server 108 may be included in the second network 199. The electronic device 101 may be applied to intelligent services (e.g., smart home, smart city, smart car, or health-care) based on 5G communication technology or IoT-related technology.

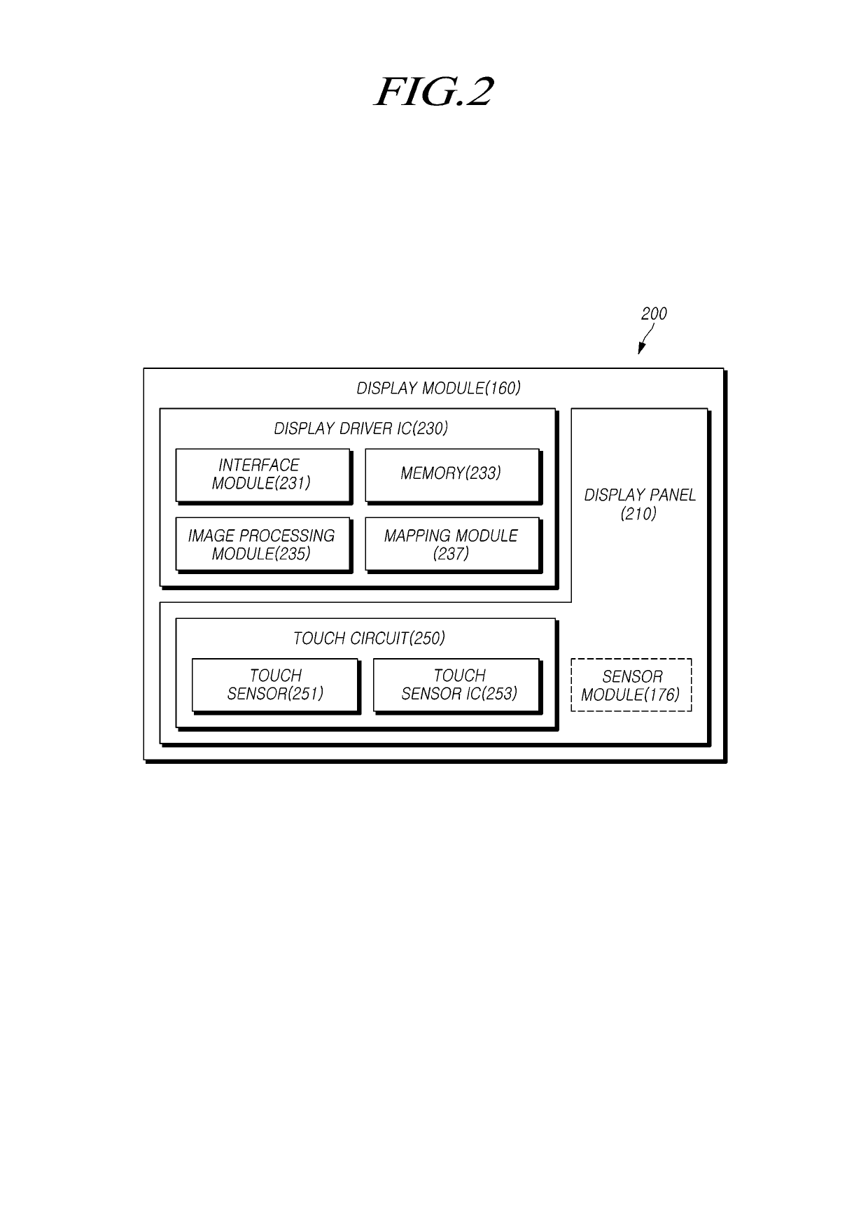

FIG. 2 illustrates a block configuration 200 of a display module 160 according to one or more embodiments.

Referring to FIG. 2, the display module 160 may include a display panel 210 and a display driver integrated circuit (IC) 230 to control the display panel 210. The display driver IC 230 may include an interface module 231, memory 233 (e.g., buffer memory), an image processing module 235, or a mapping module 237. The display driver IC 230 may receive image information that contains image data or an image control signal corresponding to a command to control the image data from another component of the electronic device 101 via the interface module 231. For example, according to one or more embodiments, the image information may be received from the processor 120 (e.g., the main processor 121 (e.g., an application processor)) or the auxiliary processor 123 (e.g., a graphics processing unit) operated independently from the function of the main processor 121. The display driver IC 230 may communicate, for example, with touch circuit 250 or the sensor module 176 via the interface module 231. The display driver IC 230 may also store at least part of the received image information in the memory 233, for example, on a frame-by-frame basis. The image processing module 235 may perform pre-processing or post-processing (e.g., adjustment of resolution, brightness, or size) with respect to at least part of the image data. According to one or more embodiments, the pre-processing or post-processing may be performed, for example, based at least in part on one or more characteristics of the image data or one or more characteristics of the display panel 210. The mapping module 237 may generate a voltage value or a current value corresponding to the image data pre-processed or post-processed by the image processing module 235. According to one or more embodiments, the generating of the voltage value or current value may be performed, for example, based at least in part on one or more attributes of the pixels (e.g., an array, such as an RGB stripe or a pentile structure, of the pixels, or the size of each subpixel) of the display panel 210. At least some pixels of the display panel 210 may be driven, for example, based at least in part on the voltage value or the current value such that visual information (e.g., a text, an image, or an icon) corresponding to the image data may be displayed via the display panel 210.

According to one or more embodiments, the display module 160 may further include the touch circuit 250. The touch circuit 250 may include a touch sensor 251 and a touch sensor IC 253 to control the touch sensor 251. The touch sensor IC 253 may control the touch sensor 251 to sense a touch input or a hovering input with respect to a certain position on the display panel 210. To achieve this, for example, the touch sensor IC 253 may detect (e.g., measure) a change in a signal (e.g., a voltage, a quantity of light, a resistance, or a quantity of one or more electric charges) corresponding to the certain position on the display panel 210. The touch sensor IC 253 may provide input information (e.g., a position, an area, a pressure, or a time) indicative of the touch input or the hovering input detected to the processor 120. According to one or more embodiments, at least part (e.g., the touch sensor IC 253) of the touch circuit 250 may be formed as part of the display panel 210 or the display driver IC 230, or as part of another component (e.g., the auxiliary processor 123) disposed outside the display module 160.

According to one or more embodiments, the display module 160 may further include at least one sensor (e.g., a fingerprint sensor, an iris sensor, a pressure sensor, or an illuminance sensor) of the sensor module 176 or a control circuit for the at least one sensor. In such a case, the at least one sensor or the control circuit for the at least one sensor may be embedded in one portion of a component (e.g., the display panel 210, the display driver IC 230, or the touch circuit 250)) of the display module 160. For example, when the sensor module 176 embedded in the display module 160 includes a biometric sensor (e.g., a fingerprint sensor), the biometric sensor may obtain biometric information (e.g., a fingerprint image) corresponding to a touch input received via a portion of the display panel 210. As another example, when the sensor module 176 embedded in the display module 160 includes a pressure sensor, the pressure sensor may obtain pressure information corresponding to a touch input received via a partial or whole area of the display panel 210. According to one or more embodiments, the touch sensor 251 or the sensor module 176 may be disposed between pixels in a pixel layer of the display panel 210, or over or under the pixel layer.

The display module 160 according to various embodiments may be included in an electronic device such as a bar type, a foldable type, a rollable type, a sliding type, a wearable type, a tablet PC, and/or a notebook PC. The display module 160 according to various embodiments of the disclosure may be included in various electronic devices as well as the above-described examples.

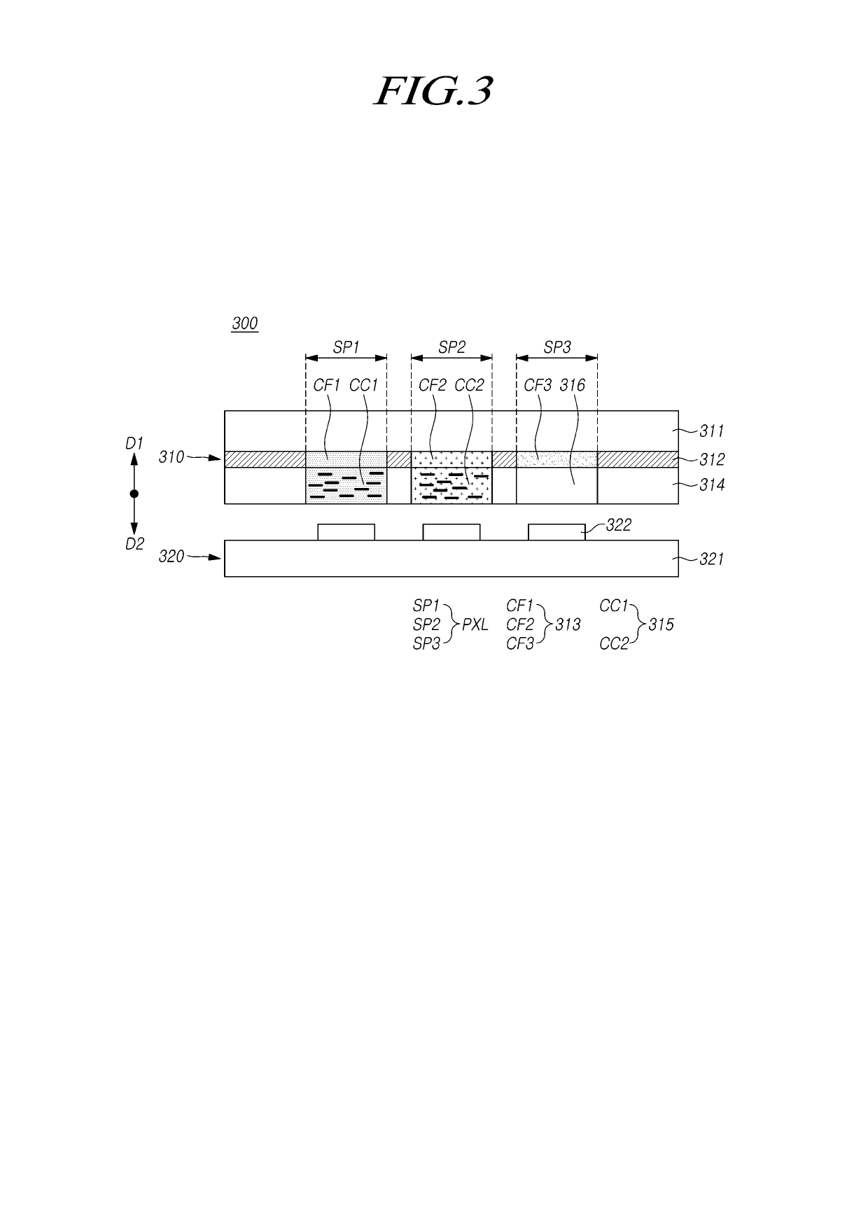

FIG. 3 illustrates a stacked structure of a display panel 300 according to one or more embodiments.

Referring to FIG. 3, a display panel 300 (e.g., the display panel 210 of FIG. 2) may include a plurality of pixels PXL that are one unit displaying an image. In FIG. 3, only one pixel PXL is exemplarily illustrated for convenience. A pixel PXL may include a plurality of subpixels SP1, SP2, and SP3 emitting different colors. As an example, each of a plurality of pixels PXL may include a first subpixel SP1 implementing red, a second subpixel SP2 implementing green, and a third subpixel SP3 implementing blue. As another example, each of the plurality of pixels PXL may include the first to third subpixels SP1, SP2, and SP3, and a fourth subpixel emitting white. The display panel 300 may display an image through control of the amount of light emitted from the respective subpixels SP1, SP2, and SP3.

The display panel 300 may include a lower substrate 320 and an upper substrate 310 facing the lower substrate 320. Although the lower substrate 320 and the upper substrate 310 illustrated in FIG. 3 are illustrated as being spaced apart, the lower substrate 320 and the upper substrate 310 may be bonded through an adhesive. For example, the lower substrate 320 and the upper substrate 310 may be bonded using an optical bonding material for transmitting light, or configured to transmit light.

The lower substrate 320 may be a substrate generating and emitting light necessary for displaying an image. The lower substrate 320 may include a rear substrate 321, a light emitting element 322, and a pixel circuit driving the light emitting element 322.

The rear substrate 321 may be a plastic substrate or a glass substrate. The rear substrate 321 may have a flexible characteristic. The light emitting element 322 and the pixel circuit may be disposed on the rear substrate 321. The light emitting element 322 may be disposed to overlap the color filter layer 313 disposed on a front substrate 311, and at least a portion of the pixel circuit may be disposed to overlap a black matrix 312 disposed on the front substrate 311.

The light emitting element 322 may include at least one of an organic light emitting diode, a quantum dot light emitting diode, an inorganic-based micro light emitting diode (micro LED), and an inorganic-based nano light emitting diode (nano LED). For example, the light emitting element 322 may be a micro light emitting diode.

The pixel circuit may be composed of a plurality of transistors. For example, the pixel circuit may be composed of a CMOS circuit including a combination of at least one N-type transistor and at least one P-type transistor.

The upper substrate 310 may include a front substrate 311, a black matrix 312, a color filter layer 313, a partition wall 314, a color conversion layer 315, and a transparent layer 316.

The front substrate 311 may be formed of a material having light transmittance. The front substrate 311 may be formed of a plastic substrate or a glass substrate. The front substrate 311 may have a flexible characteristic. The black matrix 312, the color filter layer 313, the partition wall 314, the color conversion layer 315, and the transparent layer 316 may be stacked on one surface (e.g., a surface facing the D2 direction) of the front substrate 311. An image may be provided to a viewer watching the display as light passing through the color filter layer 313 is emitted to the outside through the other surface (e.g., a surface facing the D1 direction) of the front substrate 311. In one or more embodiments, the display panel 300 may further include a low-reflection layer formed on the other surface (e.g., the surface facing the D1 direction) of the front substrate 311.

The color filter layer 313 may include a first color filter CF1, a second color filter CF2, and a third color filter CF3. The first color filter CF1 may implement the same color as light emitted from a first color conversion portion CC1. For example, the first color filter CF1 may be a red color filter. The first color filter CF1 may transmit red light and absorb color light other than the red light. The first color filter CF1 may increase the color purity of the red light incident through the first color conversion portion CC1. The second color filter CF2 may implement the same color as light emitted from a second color conversion portion CC2. For example, the second color filter CF2 may be a green color filter. The second color filter CF2 may transmit green light and absorb color light other than the green light. The second color filter CF2 may increase the color purity of the green light incident through the second color conversion portion CC2. The third color filter CF3 may implement the same color as light emitted from the light emitting element 322. For example, the third color filter CF3 may be a blue color filter. The third color filter CF3 may transmit blue light and absorb color light other than the blue light. The third color filter CF3 may increase the color purity of the blue light incident through the transparent layer 316.

The black matrix 312 may be disposed between the first color filter CF1, the second color filter CF2, and the third color filter CF3. Since the black matrix 312 divides a region of each subpixel SP1, SP2, and SP3, the black matrix 312 may overlap the partition wall 314. The black matrix 312 may be formed of a material such as metal, synthetic resin, synthetic rubber, and/or a carbon-based organic material. For example, the black matrix 312 may be composed of chromium (Cr), chromium oxide (CrOx), carbon black, or a double layer including these.

The color conversion layer 315 may include a first color conversion portion CC1 and a second color conversion portion CC2. A color conversion portion (e.g., CC1 or CC2) may include at least one color conversion particle. For example, the color conversion portion may convert the wavelength of light (e.g., blue light) by including at least one color conversion particle regularly arranged.

The first color conversion portion CC1 may be formed to overlap the first color filter CF1. The first color conversion portion CC1 may be disposed between the light emitting element 322 and the first color filter CF1. The first color conversion portion CC1 may convert light emitted from the light emitting element 322 into first color light using a first color conversion particle. For example, the first color conversion portion CC1 may convert blue light emitted from the light emitting element 322 into red light.

The second color conversion portion CC2 may be formed to overlap the second color filter CF2. The second color conversion portion CC2 may be disposed between the light emitting element 322 and the second color filter CF2. The second color conversion portion CC2 may convert light emitted from the light emitting element 322 into second color light using a second color conversion particle. For example, the second color conversion portion CC2 may convert blue light emitted from the light emitting element 322 into green light.

The transparent layer 316 may be formed to overlap the third color filter CF3. The transparent layer 316 may be disposed between the light emitting element 322 and the third color filter CF3. The transparent layer 316 may transmit light (e.g., blue light) emitted from the light emitting element 322 without color conversion. The transparent layer 316 may be in a hollow form so that incident light passes therethrough as it is, or may be formed of a transparent resin such as acrylonitrile butadiene styrene (ABS), poly methyl methacrylate (PMMA), or poly carbonate (PC).

The partition wall 314 may block movement of light between the subpixels SP1, SP2, and SP3 implementing different colors. The partition wall 314 may be formed in black color absorbing light. The partition wall 314 may be formed of a material such as metal, synthetic resin, synthetic rubber, and/or a carbon-based organic material. For example, the partition wall 314 may be composed of chromium (Cr), chromium oxide (CrOx), carbon black, or a double layer including these.

According to one or more embodiments, one surface (e.g., a surface facing the second direction D2) of the partition wall 314 and a side surface (e.g., a surface in contact with the color conversion layer 315) of the partition wall 314, and one surface (e.g., a surface in contact with a color conversion layer 315) of the color filter layer 313 may be surface-treated. The side surface of the partition wall 314 and one surface of the color filter layer 313 may be hydrophilically treated to form an attractive force with ink that is a material of the color conversion layer 315 and the transparent layer, respectively. One surface of the partition wall 314 may be hydrophobically treated to form a repulsive force with the ink. Since the color conversion layer 315 and the transparent layer 316 are not formed on one surface of the partition wall 314, a defect caused by the color conversion layer 315 and the transparent layer 316 in a bonding process of the lower substrate 320 and the upper substrate 310 may be prevented. A hole or a space in which the color conversion layer 315 and the transparent layer 316 are formed may be provided between at least two partition walls 314. The hole or the space may correspond to a size and a shape of the color conversion layer 315 and the transparent layer 316. For example, the color conversion layer 315 and the transparent layer 316 may be formed between the at least two partition walls 314 by filling the hole or the space with color conversion ink. The hole or the space may include a rod shape and may be continuously provided at a regular interval. For example, a quantum rod inside the color conversion layer 315 to be described below may be disposed such that the major axis thereof is parallel to the rod shape of the hole or the space.

In one or more embodiments, the upper substrate 310 may be completed by sequentially forming the black matrix 312, the color filter layer 313, and the partition wall 314, and then forming the color conversion layer 315 and the transparent layer 316 through electrohydrodynamic (EHD) printing. The EHD printing may form a continuous ink line using a constant air pressure and an electric field applied to a nozzle, instead of intermittent ink ejection of an inkjet process. The electrohydrodynamic printing may form the color conversion layer excellently and precisely by forming the width and height of a pattern printed with the color conversion ink to be constant. Further, since the electrohydrodynamic printing allows use of high-viscosity ink, a high color conversion ratio may be achieved because addition of a functional material capable of increasing quantum dot content or enhancing color conversion characteristics is possible.

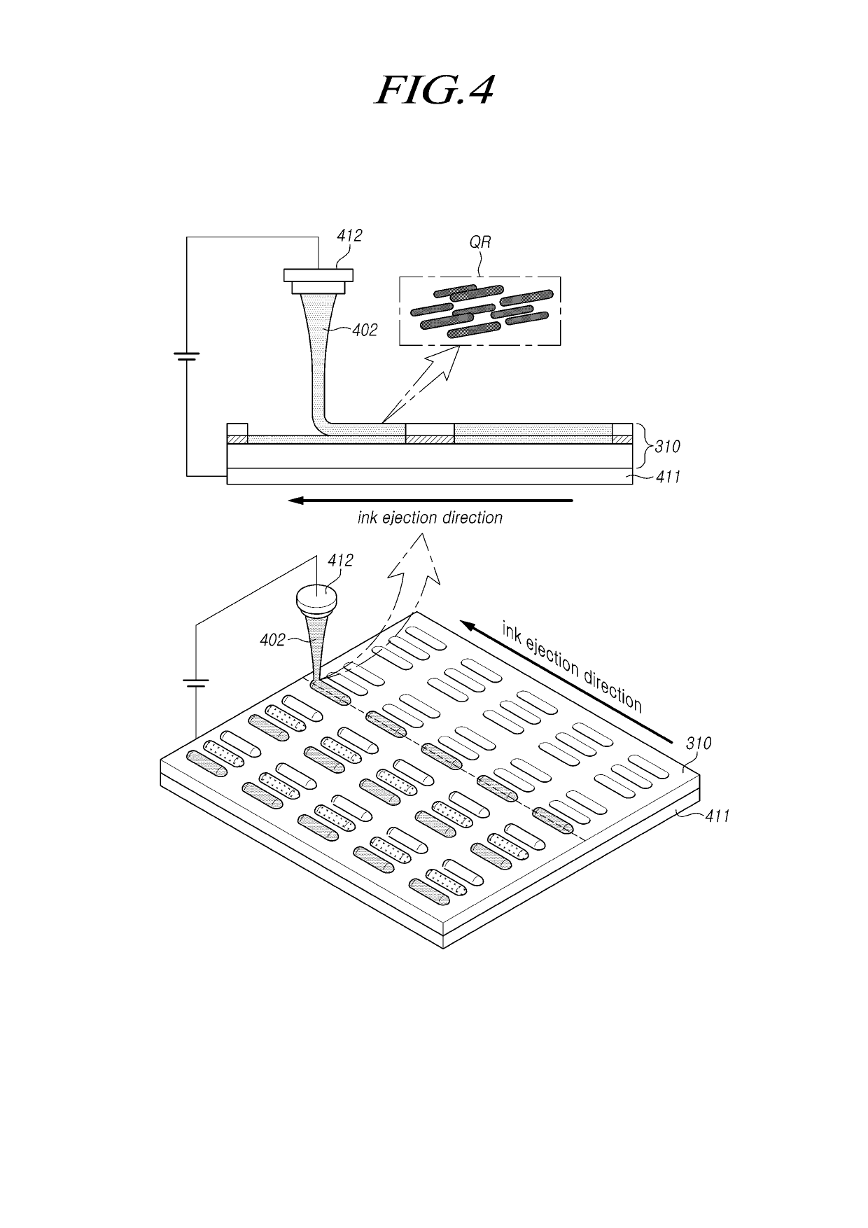

FIG. 4 illustrates a method of forming the color conversion layer 315 and the transparent layer 316 according to one or more embodiments.

Referring to FIG. 4, the color conversion layer (e.g., the color conversion layer 315 of FIG. 3) and the transparent layer (e.g., the transparent layer 316 of FIG. 3) may be formed using EHD printing. For example, the color conversion layer and the transparent layer may be manufactured through an operation of preparing color conversion ink including at least one color conversion particle, an operation of ejecting the color conversion ink using the electrohydrodynamic (EHD) printing, and an operation of aligning the at least one color conversion particle in a uniform direction based on a first force and a second force according to the electrohydrodynamic printing.

Specifically, the upper substrate 310 on which the front substrate 311, the black matrix (e.g., the black matrix 312 of FIG. 3), the color filter layer (e.g., the color filter layer 313 of FIG. 3), and the partition wall 314 are formed may be mounted on a stage 411. A nozzle 412 may be aligned to coincide with the virtual center line of each subpixel SP1, SP2, and SP3. The nozzle 412 may move in a direction perpendicular to the ground along the virtual center line. An electric field may be formed between the nozzle 412 and the stage 411 while a constant pressure is applied to the aligned nozzle 412. For example, a negative polarity voltage (e.g., a ground voltage) may be applied to the stage 411, and a positive polarity voltage (e.g., a voltage higher than the ground voltage) may be applied to the nozzle 412. The air pressure and the electric field may be controlled to have constant values to maintain a uniform flow rate of a color conversion ink 402. The color conversion ink 402 may be ink used as a material of a color conversion member (e.g., the color conversion layer 315 and the transparent layer 316 of FIG. 3). The color conversion ink 402 may include a color conversion particle (e.g., a quantum rod QR).

In one or more embodiments, the color conversion ink 402 ejected from the nozzle 412 may gather together to form a Taylor cone having an inverted triangular liquid surface. The color conversion ink 402 gathered in the Taylor cone form may be ejected in a continuous ink stream form. The color conversion layer 315 and the transparent layer 316 may be sequentially formed on the upper substrate 310 as the color conversion ink 402 is ejected from the nozzle 412 in a predetermined ejection direction (e.g., an ink ejection direction). For example, when the nozzle 412 ejects the color conversion ink 402 in a direction perpendicular to the ground, the upper substrate 310 may move along the virtual center line on the stage 411. In this case, the color conversion layer 315 and the transparent layer 316 may be formed on the upper substrate 310 by the color conversion ink 402 being applied on the upper substrate 310 according to the movement of the upper substrate 310. For example, the nozzle 412 may move (or scan) in a direction parallel to the ground along the virtual center line. In this case, the color conversion layer 315 and the transparent layer 316 may be formed on the upper substrate 310 by the color conversion ink 402 being applied on the upper substrate 310 according to the movement of the nozzle 412. For example, the color conversion portions CC1 and CC2 and the transparent layer 316 may be formed in a rod shape. The color conversion portions CC1 and CC2 and the transparent layer 316 having the rod shape may be continuously formed on the upper substrate 310 at a regular interval. For example, the color conversion portions CC1 and CC2 and the transparent layer 316 may be continuously formed on the upper substrate 310 at a regular interval by the color conversion ink including the at least one color conversion particle being ejected onto the upper substrate 310 using the electrohydrodynamic (EHD) printing. For example, the first color conversion portion CC1 may be continuously disposed at a first interval with an adjacent homogeneous first color conversion portion CC1. For example, the second color conversion portion CC2 may be continuously disposed at a second interval with an adjacent heterogeneous first color conversion portion CC1.

In one or more embodiments, when the color conversion layer 315 and the transparent layer 316 are formed, an electric field may be formed between two opposite ends of the upper substrate 310. For example, a negative polarity voltage (e.g., a ground voltage) may be applied to one end of the upper substrate 310, and a positive polarity voltage (e.g., a voltage higher than the ground voltage) may be applied to the other end of the upper substrate 310. As the electric field is formed between two opposite ends of the upper substrate 310, the arrangement of the color conversion particle (e.g., a quantum rod QR) may be maintained constant in a process of forming the color conversion layer 315 and the transparent layer 316.

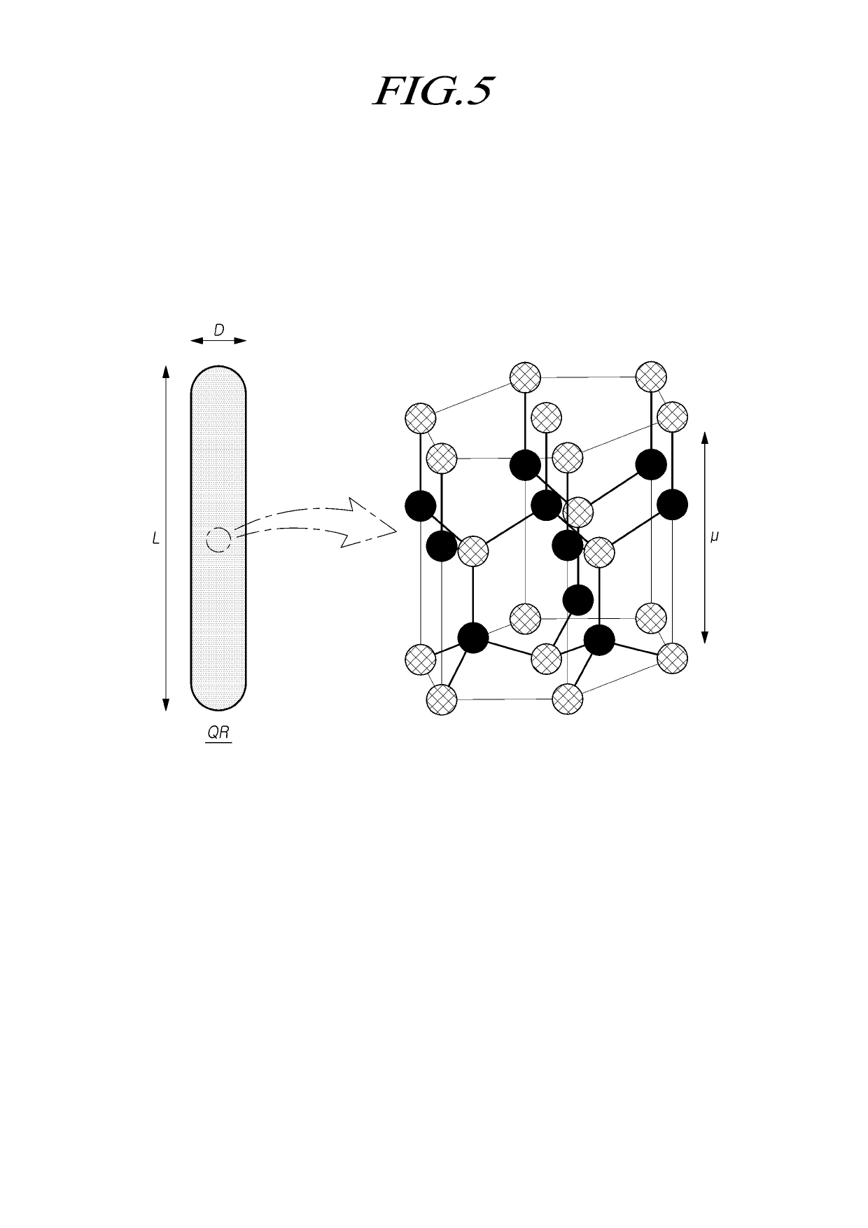

FIG. 5 illustrates a structure of a color conversion particle according to one or more embodiments.

Referring to FIGS. 4 and 5, the color conversion layer 315 may include a luminescent color conversion particle converting the wavelength of light provided from the lower substrate 320. For example, the color conversion layer 315 may include the at least one color conversion particle disposed parallel to each other by an action of at least one of a first force based on shear stress and a second force based on an electric field (E-field). The color conversion particle may exhibit quantum confinement or exciton confinement.

In one or more embodiments, the color conversion particle may include a quantum rod QR having a cylindrical shape. For example, the quantum rod QR may have a cylindrical shape with a major axis L having a predetermined length and a diameter D having a predetermined length. For example, the quantum rod QR may have the length of the major axis L of the cylindrical shape ranging from 20 nm to 200 nm. For example, the quantum rod QR may have the length of the diameter D of the cylindrical shape ranging from 3 nm to 7 nm.

In one or more embodiments, the quantum rod QR having the cylindrical shape may have a dipole moment μ. For example, the quantum rod QR may include cadmium selenide (CdSe). The quantum rod QR may have a dipole moment μ of a predetermined magnitude based on structural characteristics of the cadmium selenide (CdSe). For example, the quantum rod QR may have the magnitude of the dipole moment μ ranging from 10 Debye to 1000 Debye.

For example, the quantum rod QR of the disclosure may maximize out-coupling efficiency of the color conversion layer 315 by having the cylindrical shape having the length of the major axis L ranging from 20 nm to 200 nm and the length of the diameter D ranging from 3 nm to 7 nm, and having the magnitude of the dipole moment μ in a range of 10 Debye to 1000 Debye.

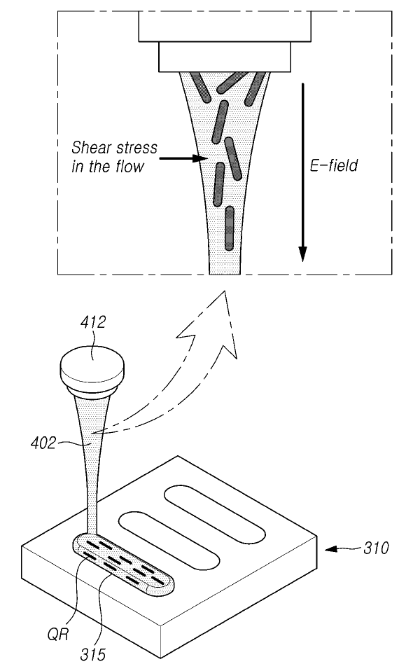

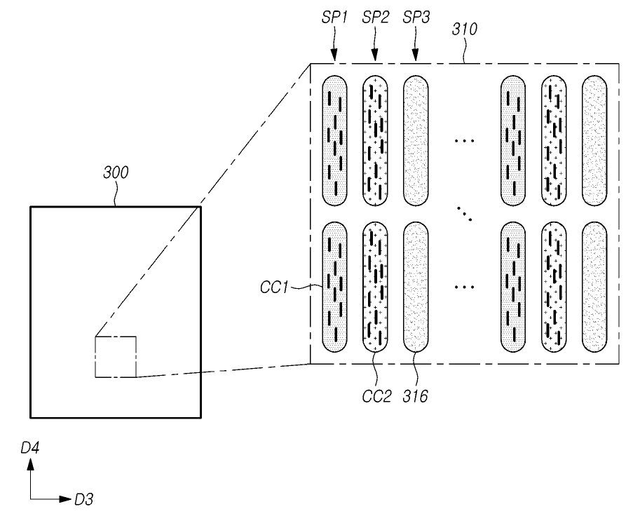

FIG. 6 illustrates a force acting in a process of forming the color conversion layer 315 and the transparent layer 316 according to one or more embodiments, and FIG. 7 illustrates the color conversion layer 315 and the transparent layer 316 formed on the upper substrate 310 according to one or more embodiments.

Referring to FIGS. 6 and 7, when the color conversion layer 315 is formed, the color conversion ink may be ejected onto the upper substrate 310 based on the electrohydrodynamic (EHD) printing. As the color conversion layer 315 is formed by the electrohydrodynamic printing, the quantum rod QR may be aligned in a uniform direction inside the color conversion layer 315. For example, when the color conversion layer 315 is formed, the color conversion ink may be subjected to a first force based on shear stress and a second force based on an electric field (E-field).

As illustrated in FIG. 6, the color conversion ink may be subjected to the first force based on the shear stress inside a Taylor cone formed as the color conversion ink is ejected from a nozzle. For example, the first force in an ejection direction of the color conversion ink may act on the quantum rod QR included in the color conversion ink based on the shear stress inside the Taylor cone. The quantum rod QR may be aligned parallel to an ejection direction (e.g., an ink ejection direction) of the color conversion ink inside the color conversion layer 315 according to an action of the first force based on the shear stress.

As illustrated in FIG. 6, the dipole moment inside the quantum rod QR may be subjected to the second force based on the electric field. For example, according to the electric field, the second force may act on the quantum rod QR to direct one end thereof in the same direction as the ejection direction of the color conversion ink and to direct the other end thereof in a direction opposite to the ejection direction of the color conversion ink. The quantum rod QR may be aligned parallel to an ejection direction (e.g., an ink ejection direction) of the color conversion ink inside the color conversion layer 315 according to the second force acting on the dipole moment by the electric field.

As illustrated in FIG. 7, the quantum rod QR may be regularly arranged in a uniform direction inside the color conversion layer 315. For example, the quantum rod QR may be aligned such that the major axis of the cylindrical shape is oriented in one direction (e.g., the D4 direction) inside the color conversion layer 315. For example, the quantum rod QR may be disposed parallel to each other inside the color conversion layer 315. The quantum rod QR may emit light in a direction perpendicular to the major axis of the cylindrical shape. For example, the quantum rod QR inside the color conversion layer 315 may emit light linearly polarized in a direction parallel to the major axis of the cylindrical shape in a direction perpendicular to the major axis.

As described above, the display panel of the disclosure may include the color conversion particle regularly arranged inside the color conversion layer 315 by forming the color conversion layer 315 using the electrohydrodynamic printing. Accordingly, the display panel of the disclosure may increase out-coupling efficiency of the color conversion layer 315 and enhance display quality.

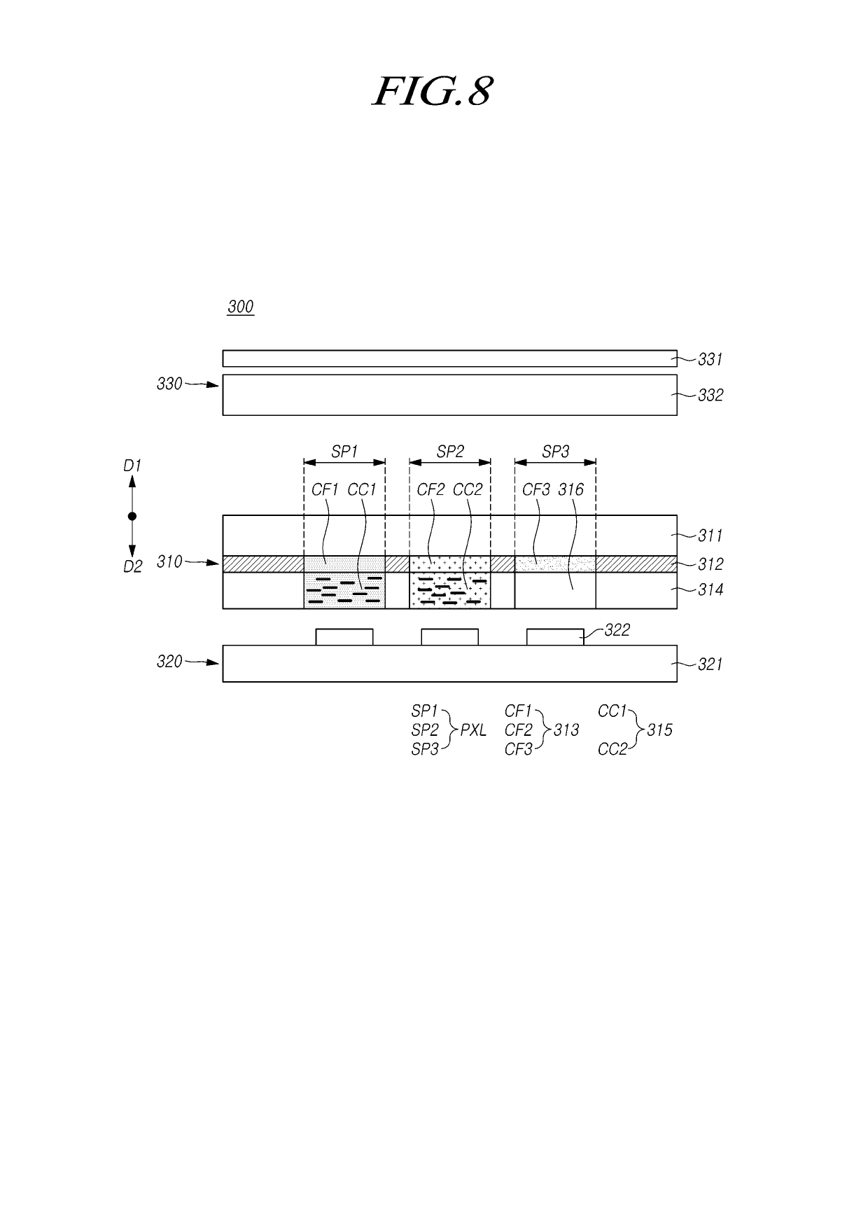

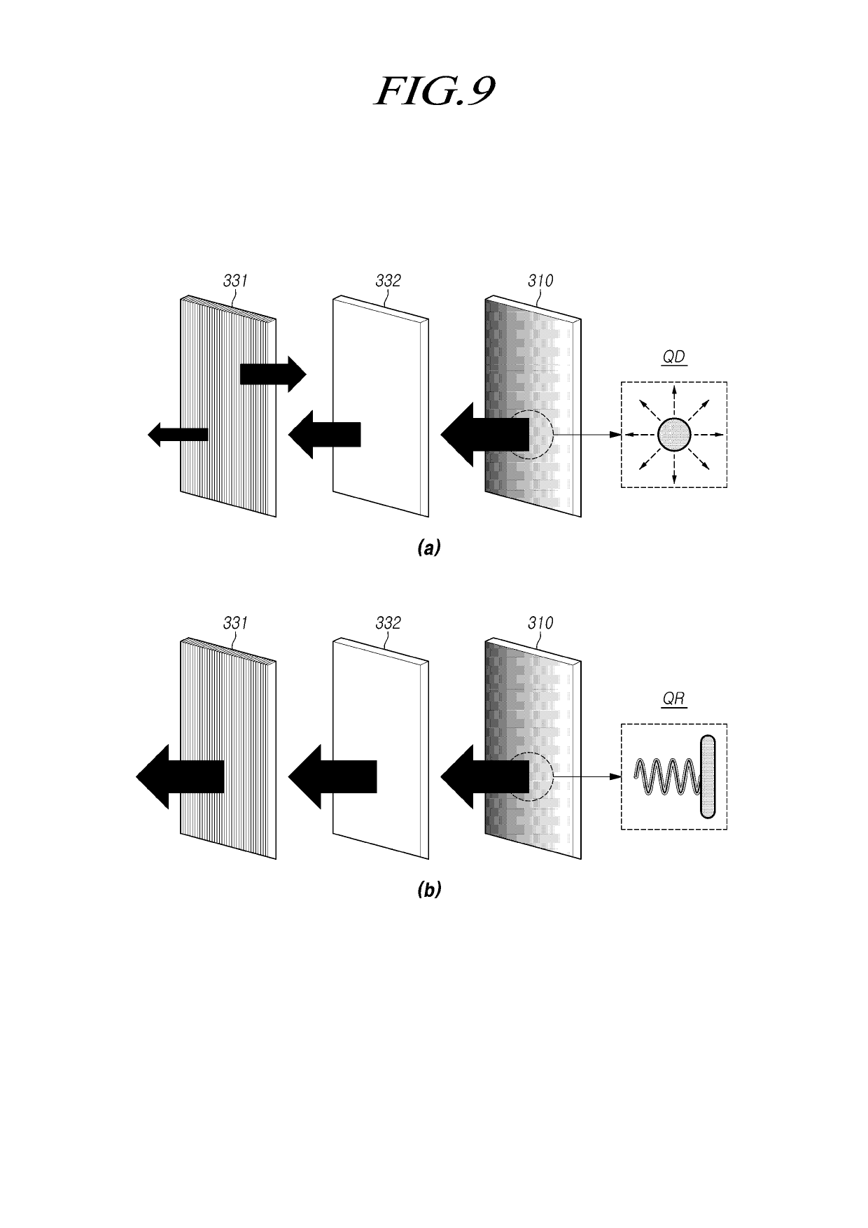

FIG. 8 illustrates a stacked structure of a display panel according to another embodiment, and FIG. 9 illustrates a change of light emitted from a display panel according to one or more embodiments.

Referring to FIG. 8, a display panel 300 may include a lower substrate 320, an upper substrate 310 facing the lower substrate 320, and a low-reflection layer 330 facing the upper substrate 310. Although the lower substrate 320 and the upper substrate 310 illustrated in FIG. 8 are illustrated as being spaced apart, the lower substrate 320 and the upper substrate 310 may be bonded through an adhesive. Similarly, although the low-reflection layer 330 and the upper substrate 310 illustrated in FIG. 8 are illustrated as being spaced apart, the low-reflection layer 330 and the upper substrate 310 may be bonded through an adhesive.

The lower substrate 320 may be a substrate generating and emitting light necessary for displaying an image. The lower substrate 320 may include a rear substrate 321, a light emitting element 322, and a pixel circuit driving the light emitting element 322.

The upper substrate 310 may be formed on one surface (e.g., a surface facing the D1 direction) of the lower substrate 320. The upper substrate 310 may include a front substrate 311, a black matrix 312, a color filter layer 313, a partition wall 314, a color conversion layer 315, and a transparent layer 316. The upper substrate 310 may convert the wavelength of light incident from the lower substrate 320 and output the converted light to the upper side.

The low-reflection layer 330 may be formed on one surface (e.g., a surface facing the D1 direction) of the upper substrate 310. The low-reflection layer 330 may include a linear polarizer 331 and a quarterwave plate 332. The low-reflection layer 330 may enhance visibility of the display panel by minimizing external light reflection. The linear polarizer 331 may pass only a specific polarization direction of incident light and block polarization in a direction perpendicular to the specific polarization direction. For example, when light polarized in a vertical direction is incident on the linear polarizer 331 passing light polarized in a horizontal direction, the light polarized in the vertical direction may be blocked. The quarterwave plate 332 may adjust the phase of light to differ by 1/4 wavelength for two orthogonal polarization directions. The quarterwave plate 332 may change linearly polarized light into circularly or elliptically polarized light. For example, when the quarterwave plate 332 is disposed on a rear surface of the linear polarizer 331, the polarized light coming from the linear polarizer 331 may be converted into circularly polarized light.

In one or more embodiments, the quantum rod inside the color conversion layer 315 may minimize light reflected from the low-reflection layer 330 by being regularly arranged inside the color conversion layer 315. For example, the linear polarizer 331 may pass light polarized in a first direction and block light polarized in a second direction perpendicular to the first direction. In this case, as illustrated in (a) of FIG. 9, light emitted from the upper substrate 310 (e.g., light emitted from a quantum dot QD) may be reflected from the linear polarizer 331 of the low-reflection layer 330 to decrease out-coupling efficiency. The quantum rod of the disclosure may be aligned in a direction parallel to the first direction inside the color conversion layer 315. For example, the quantum rod may be aligned in a direction parallel to the first direction and output light polarized in the first direction. Accordingly, as illustrated in (b) of FIG. 9, the light emitted from the quantum rod of the upper substrate 310 may be output to the outside without being reflected from the linear polarizer 331 of the low-reflection layer 330. Therefore, the color conversion layer 315 including the quantum rod may prevent a decrease in the amount of emitted light caused by the linear polarizer 331 of the low-reflection layer 330.

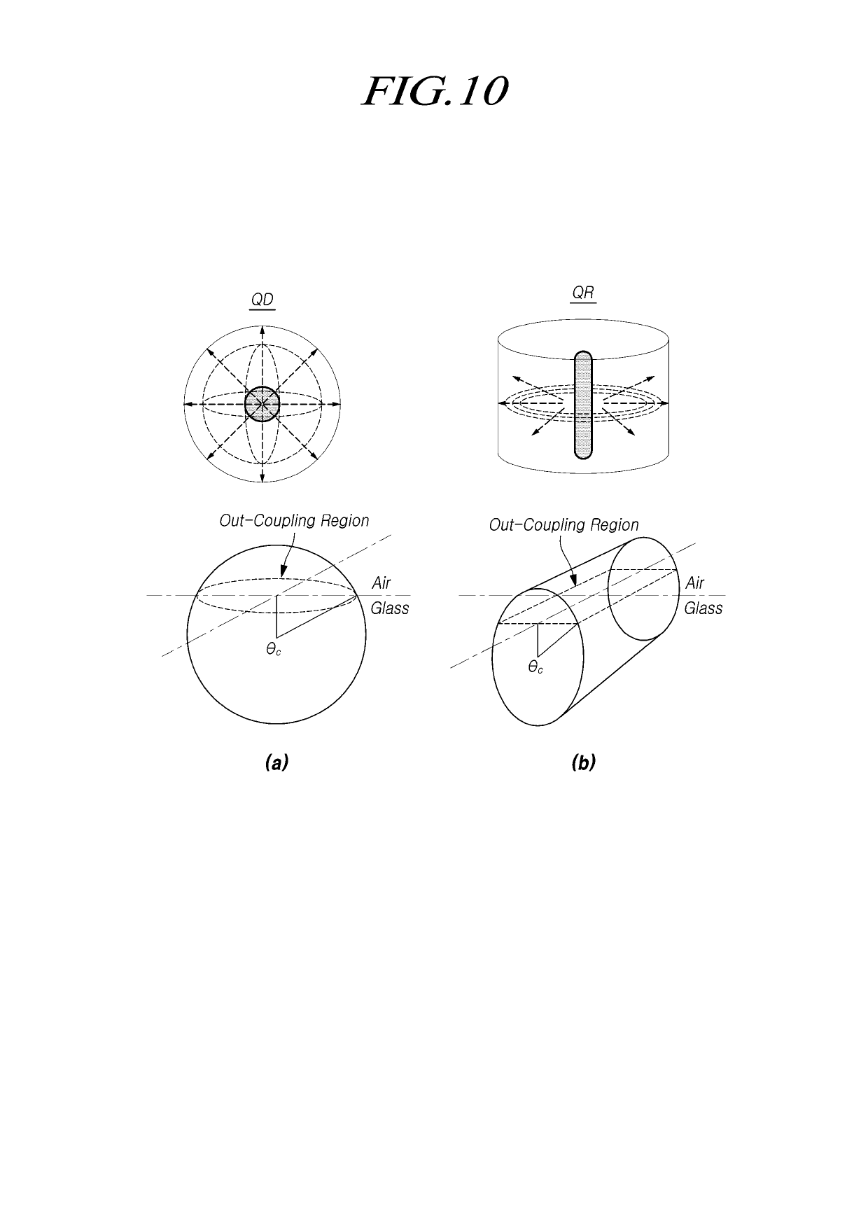

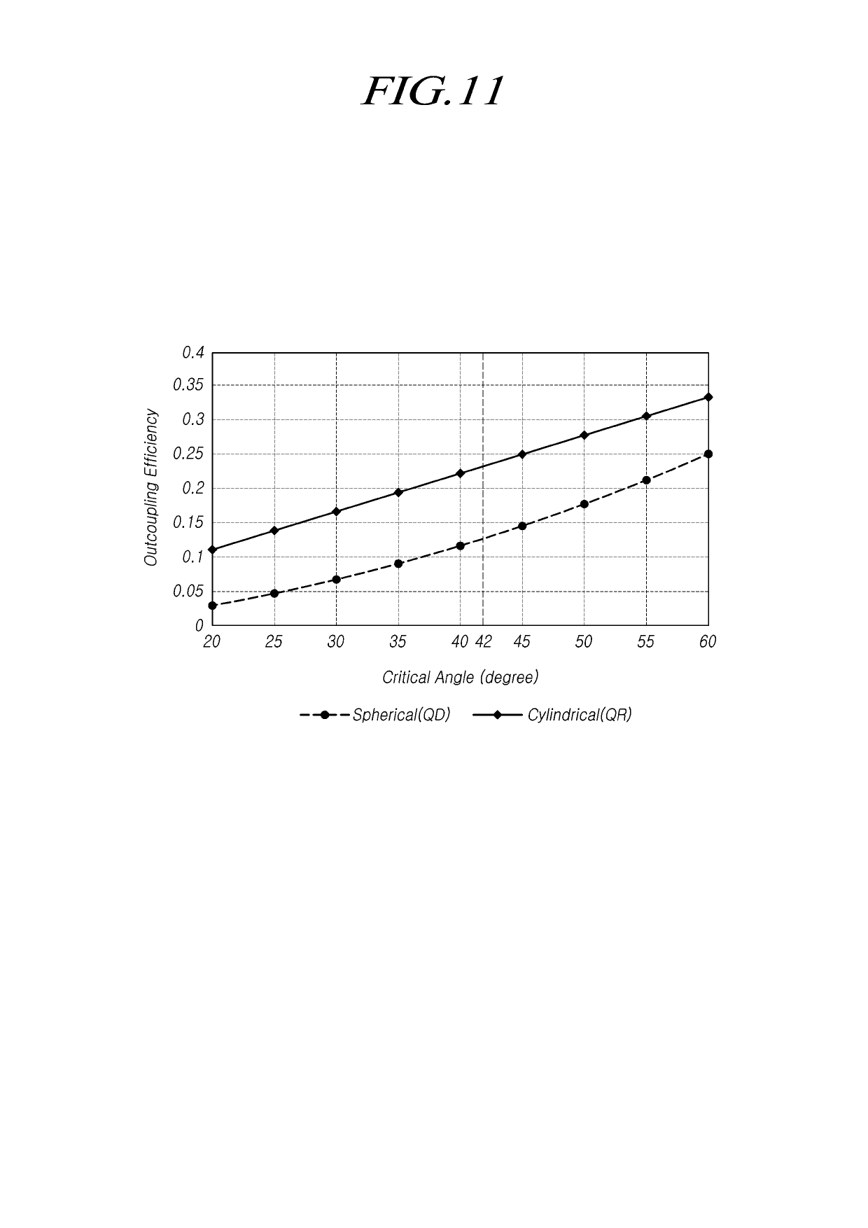

FIG. 10 illustrates an out-coupling region for each color conversion particle according to one or more embodiments, and FIG. 11 illustrates out-coupling efficiency according to a critical angle for each color conversion particle according to one or more embodiments.

Referring to FIGS. 10 and 11, the quantum rod QR having the cylindrical shape included in the color conversion layer 315 of the disclosure may include a wider out-coupling region than a quantum dot QD having a spherical shape based on the same volume. For example, as illustrated in (a) of FIG. 10, the quantum dot QD having the spherical shape may include a predetermined out-coupling region according to the surface area ratio of the spherical shape. For example, as illustrated in (b) of FIG. 10, the quantum rod QR having the cylindrical shape may include a predetermined out-coupling region according to the surface area ratio. Comparing (a) and (b) of FIG. 10, since the cylindrical shape has a wider surface area emitting light than the spherical shape based on the same volume, the quantum rod QR may include a wider out-coupling region than the quantum dot QD.

For example, as illustrated in FIG. 11, since the out-coupling region of the quantum rod QR is wider than that of the quantum dot QD, the out-coupling efficiency of the quantum rod QR may be 1.5 to 3 times or more higher than the out-coupling efficiency of the quantum dot QD in a critical angle range of 20° to 60°. In particular, referring to FIG. 11, it can be identified that at 42°, which is the critical angle between air and glass, the out-coupling efficiency of the quantum rod QR is more than twice as high as the out-coupling efficiency of the quantum dot QD.

As described above, the display panel of the disclosure may maximize the out-coupling region and increase the out-coupling efficiency of the color conversion layer 315 by including the quantum rod QR having the cylindrical shape as the color conversion particle.

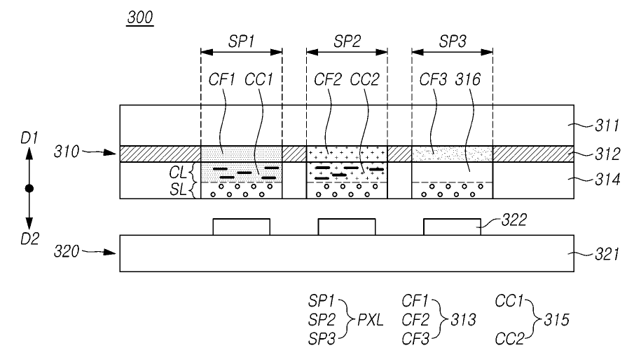

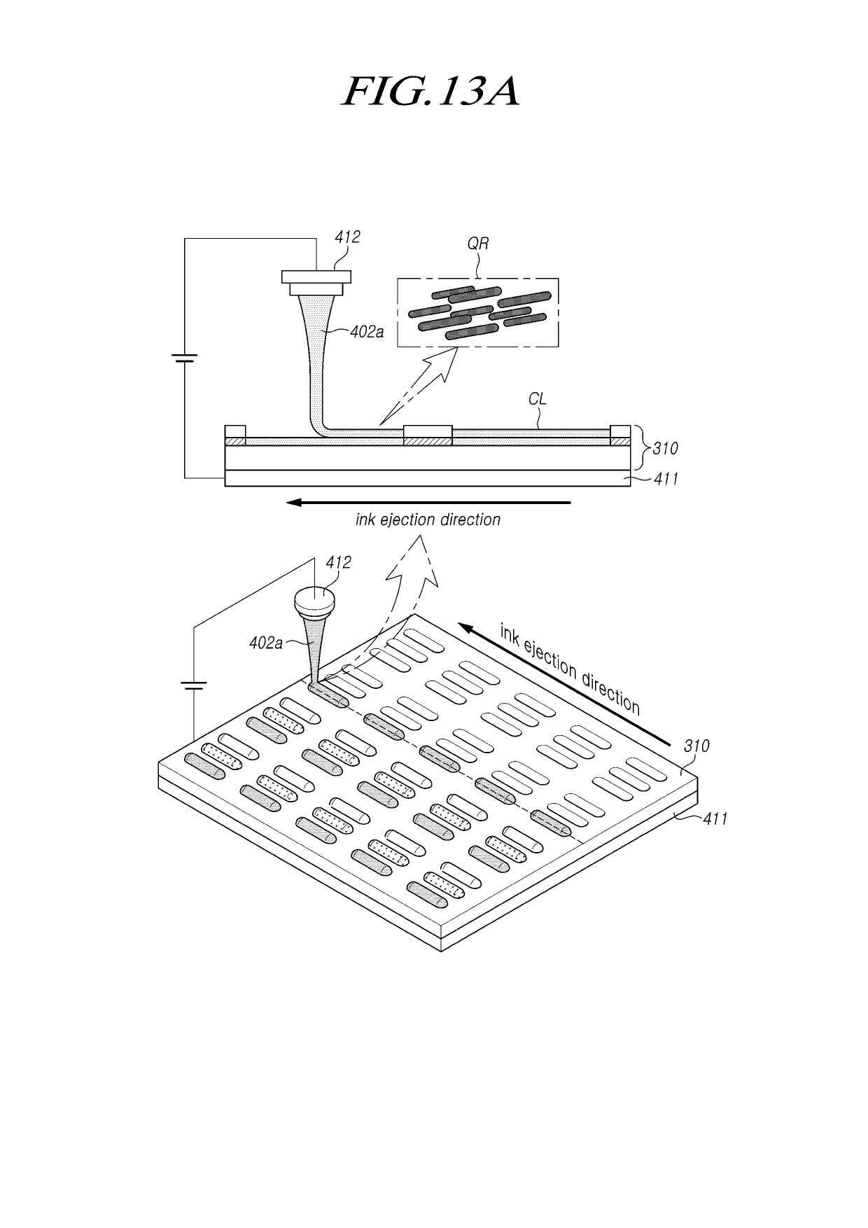

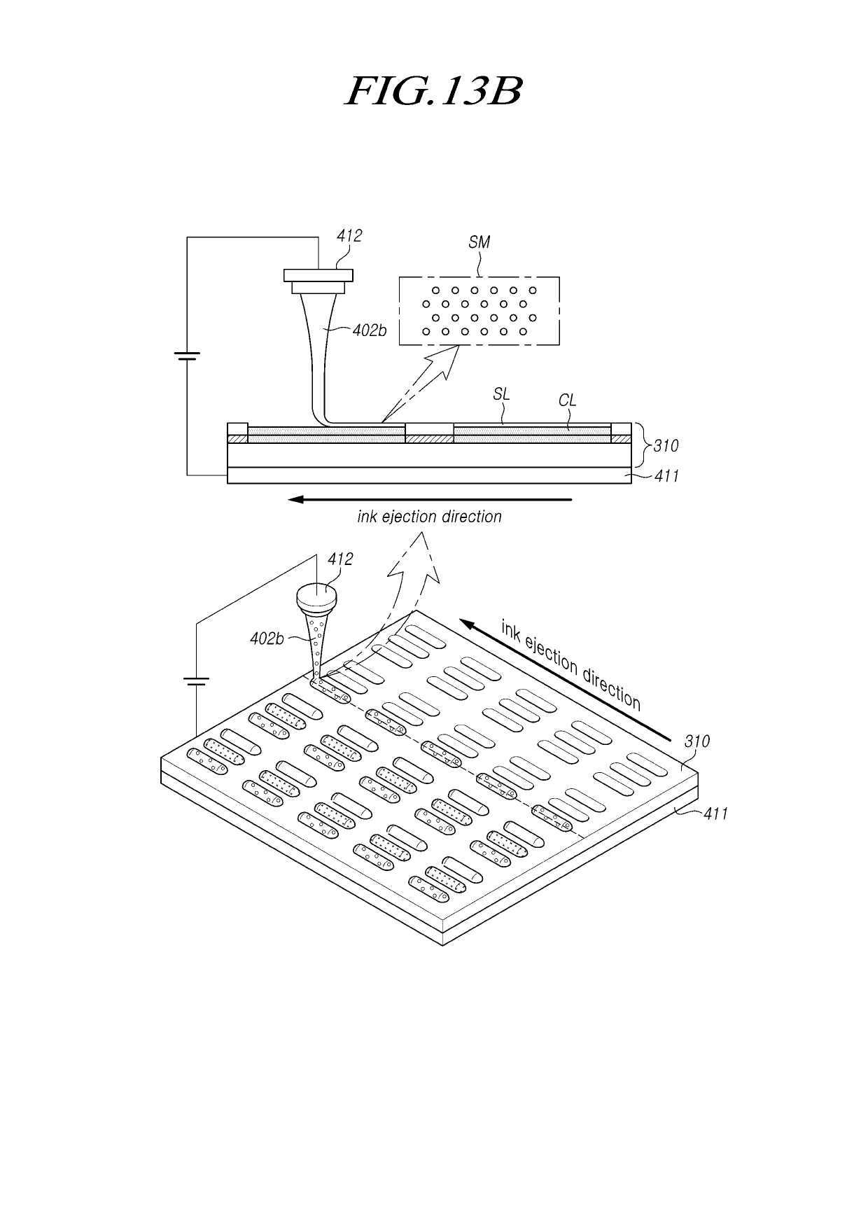

FIG. 12 illustrates a stacked structure of a display panel according to another embodiment, and FIGS. 13A and 13B illustrate a method of forming a color conversion layer and a transparent layer according to another embodiment.

Referring to FIG. 12, a display panel 300 may include a lower substrate 320 and an upper substrate 310 facing the lower substrate 320. Although the lower substrate 320 and the upper substrate 310 illustrated in FIG. 12 are illustrated as being spaced apart, the lower substrate 320 and the upper substrate 310 may be bonded through an adhesive.

The lower substrate 320 may be a substrate generating and emitting light necessary for displaying an image. The lower substrate 320 may include a rear substrate 321, a light emitting element 322, and a pixel circuit driving the light emitting element 322.

The upper substrate 310 may be formed on one surface (e.g., a surface facing the D1 direction) of the lower substrate 320. The upper substrate 310 may include a front substrate 311, a black matrix 312, a color filter layer 313, a partition wall 314, a color conversion layer 315, and a transparent layer 316. The upper substrate 310 may convert the wavelength of light incident from the lower substrate 320 and output the converted light to the upper side.

The color conversion layer 315 may include a first color conversion portion CC1 and a second color conversion portion CC2. A color conversion portion (e.g., CC1 or CC2) may include at least one color conversion particle. For example, the color conversion portion may convert the wavelength of light (e.g., blue light) by including at least one color conversion particle regularly arranged.

The first color conversion portion CC1 may be formed to overlap the first color filter CF1. The first color conversion portion CC1 may be disposed between the light emitting element 322 and the first color filter CF1. The first color conversion portion CC1 may convert light emitted from the light emitting element 322 into first color light using a first color conversion particle. For example, the first color conversion portion CC1 may convert blue light emitted from the light emitting element 322 into red light.

The second color conversion portion CC2 may be formed to overlap the second color filter CF2. The second color conversion portion CC2 may be disposed between the light emitting element 322 and the second color filter CF2. The second color conversion portion CC2 may convert light emitted from the light emitting element 322 into second color light using a second color conversion particle. For example, the second color conversion portion CC2 may convert blue light emitted from the light emitting element 322 into green light.

The transparent layer 316 may be formed to overlap the third color filter CF3. The transparent layer 316 may be disposed between the light emitting element 322 and the third color filter CF3. The transparent layer 316 may transmit light (e.g., blue light) emitted from the light emitting element 322 without color conversion. The transparent layer 316 may be in a hollow form so that incident light passes therethrough as it is, or may be formed of a transparent resin such as acrylonitrile butadiene styrene (ABS), poly methyl methacrylate (PMMA), or poly carbonate (PC).

In one or more embodiments, at least one of the first color conversion portion CC1, the second color conversion portion CC2, and the transparent layer 316 may include a color conversion particle layer CL including a color conversion particle and a scattering layer SL including a scattering material. For example, the color conversion particle layer CL may include a quantum rod QR as the color conversion particle. For example, the scattering layer SL may include TiO₂ as the scattering material. The color conversion particle layer CL and the scattering layer SL may form separate layers by being formed through independent processes. For example, the scattering layer SL may be formed below the color conversion particle layer CL. For example, a formation process of the scattering layer SL may be performed after a formation process of the color conversion particle layer CL.

Referring to FIGS. 13A and 13B, the color conversion layer (e.g., the color conversion layer 315 of FIG. 12) and the transparent layer (e.g., the transparent layer 316 of FIG. 12) may be formed using the EHD printing. For example, the color conversion layer and the transparent layer may be manufactured through an operation of preparing color conversion ink including at least one color conversion particle, an operation of ejecting the color conversion ink using the electrohydrodynamic (EHD) printing, and an operation of aligning the at least one color conversion particle in a uniform direction based on a first force and a second force according to the electrohydrodynamic printing.

Specifically, the upper substrate 310 on which the front substrate 311, the black matrix (e.g., the black matrix 312 of FIG. 12), the color filter layer (e.g., the color filter layer 313 of FIG. 12), and the partition wall 314 are formed may be mounted on a stage 411. A nozzle 412 may be aligned to coincide with the virtual center line of each subpixel SP1, SP2, and SP3. The nozzle 412 may move in a direction perpendicular to the ground along the virtual center line. An electric field may be formed between the nozzle 412 and the stage 411 while a constant pressure is applied to the aligned nozzle 412. For example, a negative polarity voltage (e.g., a ground voltage) may be applied to the stage 411, and a positive polarity voltage (e.g., a voltage higher than the ground voltage) may be applied to the nozzle 412. The air pressure and the electric field may be controlled to have constant values to maintain a uniform flow rate of a color conversion ink 402. The color conversion ink 402 may be ink used as a material of a color conversion member (e.g., the color conversion layer 315 and the transparent layer 316 of FIG. 12). For example, the color conversion ink 402 may include a quantum rod ink 402a and a scattering material ink 402b.

As illustrated in FIG. 13A, the quantum rod ink 402a ejected from the nozzle 412 may gather together to form a Taylor cone having an inverted triangular liquid surface. The quantum rod ink 402a gathered in the Taylor cone form may be ejected in a continuous ink stream form. The color conversion particle layer CL may be sequentially formed on the upper substrate 310 as the quantum rod ink 402a is ejected from the nozzle 412 in a predetermined ejection direction (e.g., an ink ejection direction). For example, the color conversion particle layer CL may be continuously formed on the upper substrate 310 at a regular interval by the quantum rod ink 402a including the quantum rod QR being ejected onto the upper substrate 310 using the electrohydrodynamic (EHD) printing.

As illustrated in FIG. 13B, the scattering material ink 402b ejected from the nozzle 412 may gather together to form a Taylor cone having an inverted triangular liquid surface. The scattering material ink 402b gathered in the Taylor cone form may be ejected in a continuous ink stream form, and the scattering layer SL may be sequentially formed on the color conversion particle layer CL formed in the process of FIG. 13A as the scattering material ink 402b is ejected from the nozzle 412 in a predetermined ejection direction (e.g., an ink ejection direction). For example, the scattering layer SL may be continuously formed on the upper substrate 310 at a regular interval by the scattering material ink 402b including the scattering material SM being ejected onto the color conversion particle layer CL using the electrohydrodynamic (EHD) printing.

As described above, in the color conversion layer 315 of the display panel of the disclosure, the scattering layer SL may be disposed below the color conversion particle layer CL through a process separate from the color conversion particle layer CL. According to such a structure of the color conversion layer 315, the scattering layer SL may increase light absorbed by the quantum rod QR of the color conversion particle layer CL by scattering light (e.g., blue light) emitted from the light emitting element 322, and at the same time may prevent scattering of converted light emitted upward from the quantum rod QR. Therefore, the display panel of the disclosure may maximize out-coupling efficiency by the color conversion layer 315.

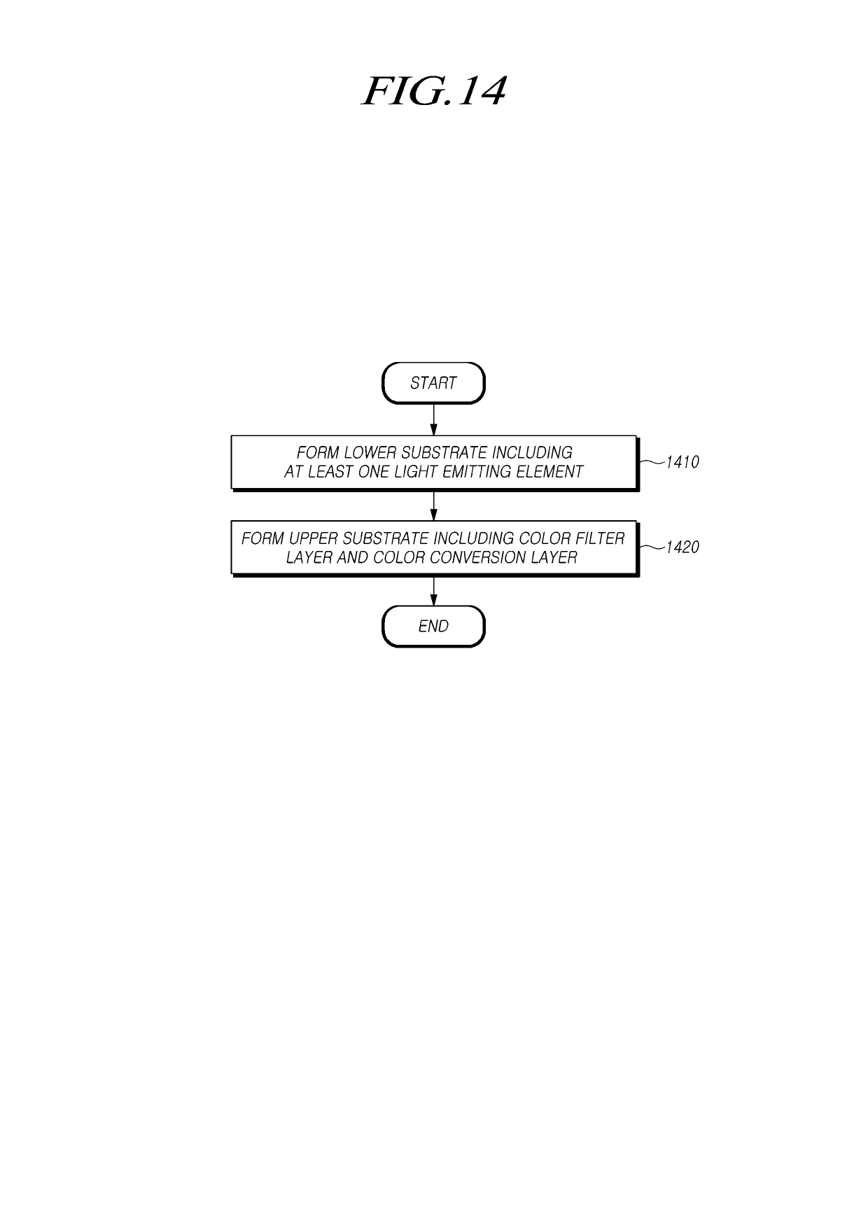

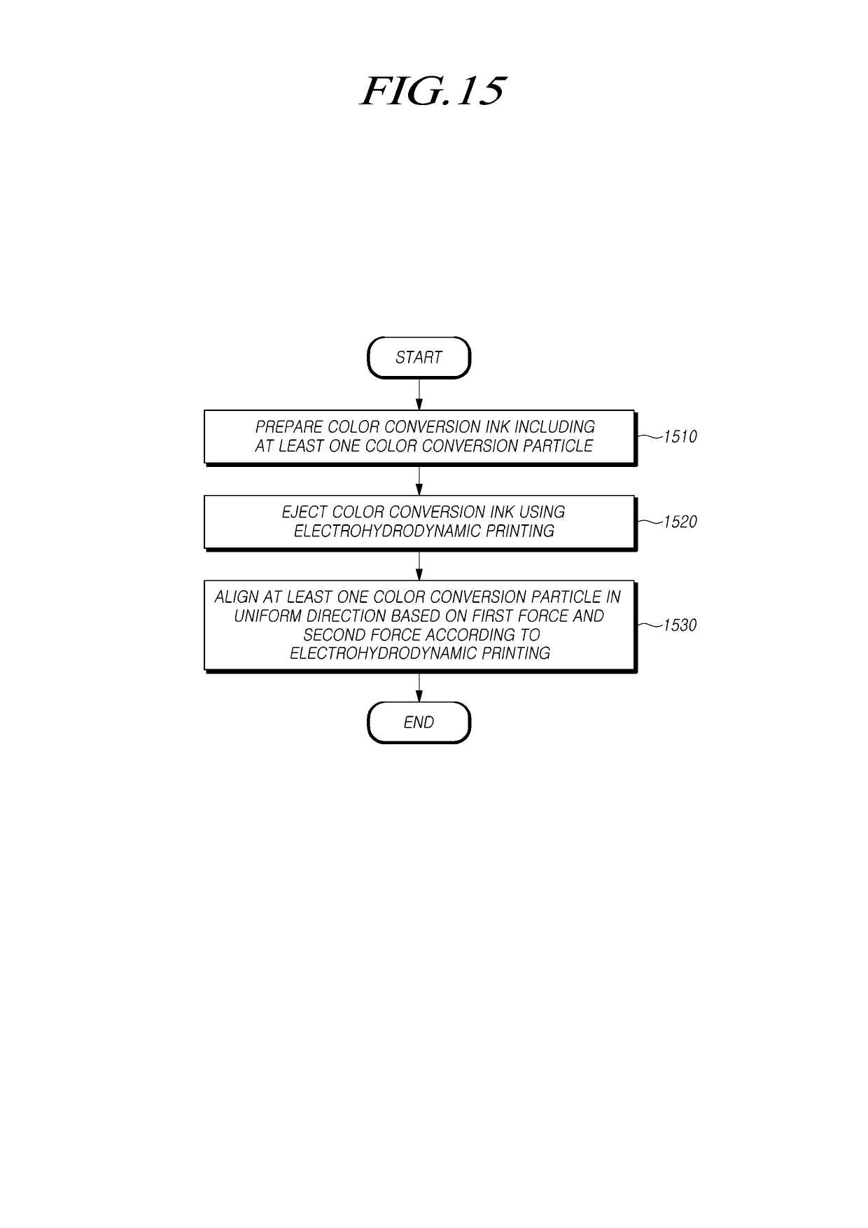

FIG. 14 illustrates a method for manufacturing a display device according to one or more embodiments, and FIG. 15 illustrates an order of an operation of manufacturing a color conversion layer of an upper substrate according to one or more embodiments.

Referring to FIG. 14, the method for manufacturing a display device of the disclosure may form a lower substrate including at least one light emitting element (operation 1410) and form an upper substrate including a color filter layer and a color conversion layer (operation 1420). For example, the method for manufacturing a display panel may form a lower substrate, form an upper substrate, and bond the lower substrate and the upper substrate using an optical bonding material for transmitting light, or configured to transmit light.

According to an example, in operation 1410, the method for manufacturing a display device may form a lower substrate generating and emitting light necessary for displaying an image. For example, the method for manufacturing a display device may form a rear substrate, form a light emitting element on the rear substrate, and form a pixel circuit driving the light emitting element on the rear substrate.

According to an example, in operation 1420, the method for manufacturing a display device may form an upper substrate outputting light incident from the lower substrate to the outside. For example, the method for manufacturing a display device may form a front substrate, form a black matrix on the front substrate, form a color filter layer on the front substrate, form a partition wall on the front substrate, and form a color conversion layer and a transparent layer on the front substrate.

Referring to FIG. 15, when the method for manufacturing a display panel of the disclosure forms the color conversion layer of the upper substrate, the method may prepare color conversion ink including at least one color conversion particle (1510), eject the color conversion ink using electrohydrodynamic (EHD) printing (1520), and align the at least one color conversion particle in a uniform direction based on a first force based on shear stress according to the electrohydrodynamic printing and a second force based on an electric field (1530). In one or more embodiments, the at least one color conversion particle may include a quantum rod having a cylindrical shape. For example, the quantum rod may have a cylindrical shape with a major axis having a predetermined length and a diameter having a predetermined length. For example, the quantum rod having the cylindrical shape may have a dipole moment based on structural characteristics.

For example, the upper substrate may be completed by sequentially forming a black matrix, a color filter layer, and a partition wall, and then forming a color conversion layer and a transparent layer through electrohydrodynamic printing. The EHD printing may form a continuous ink line using a constant air pressure and an electric field applied to a nozzle, instead of intermittent ink ejection of an inkjet process. The electrohydrodynamic printing may form the color conversion layer excellently and precisely by forming the width and height of a pattern printed with the color conversion ink to be constant. Further, since the electrohydrodynamic printing allows use of high-viscosity ink, a high color conversion ratio may be achieved because addition of a functional material capable of increasing quantum dot content or enhancing color conversion characteristics is possible.

As described above, the method for manufacturing a display device of the disclosure may regularly arrange the color conversion particle inside the color conversion layer by forming the color conversion layer using the electrohydrodynamic printing. Further, the method for manufacturing a display device of the disclosure may maximize an out-coupling region and minimize light reflected after emission, by including the quantum rod having a cylindrical shape as the color conversion particle.

Accordingly, the method for manufacturing a display device of the disclosure may increase out-coupling efficiency of the color conversion layer and enhance display quality. However, since this has been described above, no duplicate description is given.

The display device according to various embodiments of the disclosure may be one of various types of electronic devices. The display devices may include, for example, a portable communication device (e.g., a smartphone), a computer device, a portable multimedia device, a portable medical device, a camera, a wearable device, or a home appliance. The display devices according to one or more embodiments of the disclosure are not limited to the above-described devices.

It should be appreciated that various embodiments of the present disclosure and the terms used therein are not intended to limit the technological features set forth herein to particular embodiments and include various changes, equivalents, or replacements for a corresponding embodiment. As used herein, the singular forms “a,” “an,” and “the” are intended to include the plural forms as well, unless the context clearly indicates otherwise. As used herein, the term ‘and/or’ should be understood as encompassing any and all possible combinations by one or more of the enumerated items. As used herein, the terms “include,” “have,” and “comprise” are used merely to designate the presence of the feature, component, part, or a combination thereof described herein, but use of the term does not exclude the likelihood of presence or adding one or more other features, components, parts, or combinations thereof. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

As used herein, the term “part” or “module” may include a unit implemented in hardware, software, or firmware, and may interchangeably be used with other terms, for example, “logic,” “logic block,” “part,” or “circuitry”. A part or module may be a single integral component, or a minimum unit or part thereof, adapted to perform one or more functions. For example, according to one or more embodiments, ‘part’ or ‘module’ may be implemented in a form of an application-specific integrated circuit (ASIC).

As used in various embodiments of the disclosure, the term “if” may be interpreted as “when,” “upon,” “in response to determining,” or “in response to detecting,” depending on the context. Similarly, “if A is determined” or “if A is detected” may be interpreted as “upon determining A” or “in response to determining A”, or “upon detecting A” or “in response to detecting A”, depending on the context.

The program executed by the electronic device described herein may be implemented as a hardware component, a software component, and/or a combination thereof. The program may be executed by any system capable of executing computer readable instructions.

The software may include computer programs, codes, instructions, or combinations of one or more thereof and may configure the processing device as it is operated as desired or may instruct the processing device independently or collectively. The software may be implemented as a computer program including instructions stored in computer-readable storage media. The computer-readable storage media may include, e.g., magnetic storage media (e.g., read-only memory (ROM), random-access memory (RAM), floppy disk, hard disk, etc.) and an optically readable media (e.g., CD-ROM or digital versatile disc (DVD). Further, the computer-readable storage media may be distributed to computer systems connected via a network, and computer-readable codes may be stored and executed in a distributed manner. The computer program may be distributed (e.g., downloaded or uploaded) via an application store (e.g., Play Store™), directly between two UEs (e.g., smartphones), or online. If distributed online, at least part of the computer program product may be temporarily generated or at least temporarily stored in the machine-readable storage medium, such as memory of the manufacturer’s server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed:

1. A display device, comprising:
a display panel for displaying an image; and
a display driver integrated circuit (IC) for controlling the display panel, wherein the display panel comprises:
a lower substrate comprising at least one light emitting element; and
an upper substrate comprising a color filter layer and a color conversion layer, wherein the color conversion layer comprises:
at least one color conversion portion having a rod shape, wherein the at least one color conversion portion comprises at least one color conversion particle regularly arranged for converting a wavelength of light, and the at least one color conversion portion is continuously formed on the upper substrate at a regular interval.

2. The display device of claim 1, wherein the at least one color conversion portion is continuously disposed at a first interval with an adjacent homogeneous color conversion portion and continuously disposed at a second interval with an adjacent heterogeneous color conversion portion, by ejecting a color conversion ink onto the upper substrate using electrohydrodynamic (EHD) printing, the color conversion ink comprising the at least one color conversion particle.

3. The display device of claim 2, wherein the at least one color conversion particle comprises a quantum rod having a cylindrical shape.

4. The display device of claim 3, wherein the color conversion layer includes the at least one color conversion portion formed in the rod shape between partition walls, by moving the upper substrate in a first direction along a virtual center line when the color conversion ink is ejected.

5. The display device of claim 3, wherein the quantum rod is aligned parallel to an ejection direction of the color conversion ink inside the color conversion layer, by being subjected to a first force based on a shear stress inside a Taylor cone formed as the color conversion ink is ejected from a nozzle.

6. The display device of claim 3, wherein the quantum rod is aligned parallel to an ejection direction of the color conversion ink inside the color conversion layer, by a dipole moment inside the quantum rod being subjected to a second force based on an electric field.

7. The display device of claim 3, wherein the quantum rod has a length of a major axis of the cylindrical shape in a range of 20 nm to 200 nm and a length of a diameter of the cylindrical shape in a range of 3 nm to 7 nm.

8. The display device of claim 3, further comprising a low-reflection layer formed on the upper substrate, the low-reflection layer comprising a linear polarizer and a quarterwave plate.

9. The display device of claim 8, wherein the linear polarizer passes light polarized in a first direction and blocks light polarized in a second direction perpendicular to the first direction, and wherein the quantum rod is aligned in a direction parallel to the first direction inside the color conversion layer.

10. The display device of claim 1, wherein the upper substrate is manufactured through a process independent from the lower substrate, and wherein the upper substrate and the lower substrate are bonded using an optical bonding material configured to transmit light.

11. A method for manufacturing a display device including a color conversion particle, comprising:
forming a lower substrate comprising at least one light emitting element; and
forming an upper substrate comprising a color filter layer and a color conversion layer,
wherein the color conversion layer comprises at least one color conversion portion having a rod shape, and
wherein the at least one color conversion portion comprises at least one color conversion particle regularly arranged for converting a wavelength of light, and the at least one color conversion portion is continuously formed on the upper substrate at a regular interval.

12. The method of claim 11, wherein the at least one color conversion portion is continuously disposed at a first interval with an adjacent homogeneous color conversion portion and continuously disposed at a second interval with an adjacent heterogeneous color conversion portion, by ejecting a color conversion ink onto the upper substrate using electrohydrodynamic (EHD) printing, the color conversion ink comprising the at least one color conversion particle.

13. The method of claim 12, wherein the at least one color conversion particle comprises a quantum rod having a cylindrical shape.

14. The method of claim 13, wherein the color conversion layer includes the at least one color conversion portion formed in the rod shape between partition walls, by moving the upper substrate in a first direction along a virtual center line when the color conversion ink is ejected.

15. The method of claim 13, wherein forming the upper substrate aligns the quantum rod parallel to an ejection direction of the color conversion ink inside the color conversion layer, using a first force based on a shear stress inside a Taylor cone formed as the color conversion ink is ejected from a nozzle.
